(19) United States
(12) Patent Application Publication
(10) Pub. No.: US 2024/0130196 A1
(43) Pub. Date: Apr. 18, 2024

(54) DISPLAY DEVICE AND MANUFACTURING METHOD OF THE SAME

(71) Applicant: Japan Display Inc., Tokyo (JP)

(72) Inventor: Kaichi FUKUDA, Tokyo (JP)

(73) Assignee: Japan Display Inc., Tokyo (JP)

(21) Appl. No.: 18/482,326

(22) Filed: Oct. 6, 2023

(30) Foreign Application Priority Data
Oct. 13, 2022 (JP) 2022-164742

(51) Int. Cl. H10K 59/80; H10K 71/16; H10K 71/60

(52) U.S. Cl. CPC H10K 59/80518; H10K 59/80524; H10K 59/871; H10K 59/879; H10K 71/164; H10K 71/60; H10K 2102/351

(57) ABSTRACT

According to one embodiment, a display device includes a base electrode, a rib including an aperture overlapping the base electrode, a lower electrode disposed at the aperture and electrically connected to the base electrode, a partition including a lower part disposed on the rib and an upper part projecting from a side surface of the lower part, a organic layer covering the lower electrode, and a upper electrode disposed on the organic layer. A periphery of the base electrode is covered by the rib. The base electrode is formed of a first metal material. A periphery of the lower electrode is located on the rib. The lower electrode is formed of a second metal material different from the first metal material.

### CROSS-REFERENCE TO RELATED APPLICATIONS

This application is based upon and claims the benefit of priority from Japanese Patent Application No. 2022-164742, filed Oct. 13, 2022, the entire contents of which are incorporated herein by reference.

### FIELD

Embodiments described herein relate generally to a display device and a manufacturing method of the same.

### BACKGROUND

In recent years, display devices to which organic light-emitting diodes (OLEDs) are applied as display elements have been put into practical use. The display elements comprise a lower electrode, an organic layer covering the lower electrode, and an upper electrode covering the organic layer.

In the display devices as described above, a technique for improving the luminous efficacy of the display elements has been required.

### BRIEF DESCRIPTION OF THE DRAWINGS

FIG. 1 is a diagram showing a configuration example of a display device DSP according to an embodiment.

FIG. 2 is a diagram showing an example of the layout of subpixels SP1, SP2, and SP3.

FIG. 3 is a cross-sectional view showing a configuration example of the display device DSP along line A-B in FIG. 2.

FIG. 4 is a diagram showing simulation results of reflectance.

FIG. 5 is a diagram in which the results shown in FIG. 4 are grouped according to wavelength range.

FIG. 6 is a diagram showing an example of a layered structure which can be applied to organic layers OR1, OR2, and OR3.

FIG. 7 is a schematic cross-sectional view showing a partition 6 between the subpixel SP1 and the subpixel SP2 and its vicinity in an enlarged manner.

FIG. 8 is a flowchart showing an example of a manufacturing method of the display device DSP.

FIG. 9 is a schematic cross-sectional view showing a manufacturing process of the display device DSP.

FIG. 10 is a schematic cross-sectional view showing the manufacturing process subsequent to FIG. 9.

FIG. 11 is a schematic cross-sectional view showing the manufacturing process subsequent to FIG. 10.

FIG. 12 is a schematic cross-sectional view showing the manufacturing process subsequent to FIG. 11.

FIG. 13 is a schematic cross-sectional view showing the manufacturing process subsequent to FIG. 12.

FIG. 14 is a schematic cross-sectional view showing the manufacturing process subsequent to FIG. 13.

FIG. 15 is a schematic cross-sectional view showing the manufacturing process subsequent to FIG. 14.

FIG. 16 is a schematic cross-sectional view showing the manufacturing process subsequent to FIG. 15.

FIG. 17 is a schematic cross-sectional view showing the manufacturing process subsequent to FIG. 16.

FIG. 18 is a schematic cross-sectional view showing the manufacturing process subsequent to FIG. 17.

FIG. 19 is a schematic cross-sectional view showing the manufacturing process subsequent to FIG. 18.

FIG. 20 is a cross-sectional view showing another configuration example of the display device DSP.

FIG. 21 is a schematic cross-sectional view showing a manufacturing process of the display device DSP shown in FIG. 20.

### DETAILED DESCRIPTION

The embodiments described herein aim to provide a display device which can improve luminous efficacy and a manufacturing method of the same.

In general, according to one embodiment, a display device comprises a substrate, a first base electrode disposed above the substrate, a rib formed of an inorganic insulating material and comprising an aperture overlapping the first base electrode, a first lower electrode disposed at the aperture and electrically connected to the first base electrode, a partition including a conductive lower part disposed on the rib and an upper part projecting from a side surface of the lower part, a first organic layer configured to emit light of a first color and covering the first lower electrode, and a first upper electrode disposed on the first organic layer and contacting the lower part. A periphery of the first base electrode is covered by the rib. The first base electrode is formed of a first metal material. A periphery of the first lower electrode is located on the rib. The first lower electrode is formed of a second metal material different from the first metal material.

According to another embodiment, a manufacturing method of a display device, comprising forming a metal layer of a first metal material above a substrate, patterning the metal layer and forming a first base electrode, forming a rib comprising an aperture overlapping the first base electrode and a partition including a conductive lower part located on the rib and an upper part projecting from a side surface of the lower part, depositing a second metal material different from the first metal material and forming a first lower electrode electrically connected to the first base electrode, forming a first organic layer on the first lower electrode, and forming a first upper electrode which located on the first organic layer and is in contact with the lower part.

Embodiments will be described hereinafter with reference to the accompanying drawings.

The disclosure is merely an example, and proper changes within the spirit of the invention, which are easily conceivable by a skilled person, are included in the scope of the invention as a matter of course. In addition, in some cases, in order to make the description clearer, the widths, thicknesses, shapes, etc., of the respective parts are schematically illustrated in the drawings, compared to the actual modes. However, the schematic illustration is merely an example, and adds no restrictions to the interpretation of the invention. Besides, in the specification and drawings, the same or similar elements as or to those described in connection with preceding drawings or those exhibiting similar functions are denoted by like reference numerals, and a detailed description thereof is omitted unless otherwise necessary.

In the drawings, in order to facilitate understanding, an X-axis, a Y-axis and a Z-axis orthogonal to each other are shown depending on the need. A direction parallel to the X-axis is referred to as a first direction X. A direction parallel to the Y-axis is referred to as a second direction Y. A direction parallel to the Z-axis is referred to as a third direction Z. When various types of elements are viewed parallel to the third direction Z, the appearance is defined as a plan view.

A display device of the present embodiment is an organic electroluminescent display device comprising an organic light-emitting diode (OLED) as a display element, and can be mounted in a television, a personal computer, in-vehicle equipment, a tablet terminal, a smartphone, a mobile telephone, etc.

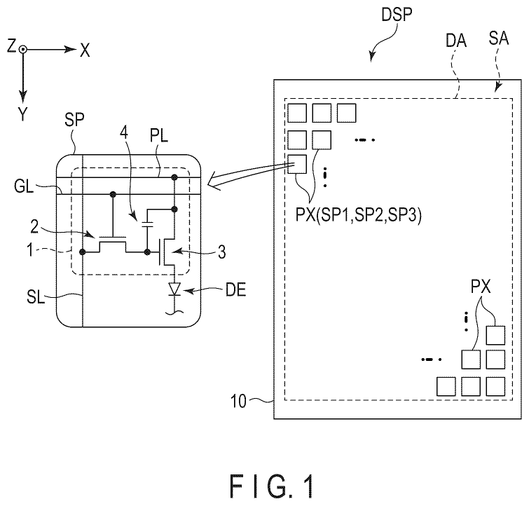

FIG. 1 is a diagram showing a configuration example of the display device DSP according to the present embodiment.

The display device DSP comprises a display area DA where an image is displayed and a surrounding area SA surrounding the display area DA on an insulating substrate 10. The substrate 10 may be glass or a resin film having flexibility.

In the present embodiment, the shape of the substrate 10 in plan view is a rectangle. Note that the shape of the substrate 10 in plan view is not limited to a rectangle, and may be another shape such as a square, a circle, or an ellipse.

The display area DA comprises pixels PX arrayed in a matrix in the first direction X and the second direction Y. The pixels PX include subpixels SP. For example, the pixels PX include a blue (first color) subpixel SP1, a green (second color) subpixel SP2, and a red (third color) subpixel SP3. The pixels PX may include a subpixel SP of another color such as white, in addition to the subpixels SP1, SP2, and SP3 or instead of one of the subpixels SP1, SP2, and SP3.

The subpixels SP each comprise a pixel circuit 1 and a display element DE driven by the pixel circuit 1. The pixel circuit 1 comprises a pixel switch 2, a drive transistor 3, and a capacitor 4. The pixel switch 2 and the drive transistor 3 are, for example, switching elements composed of thin-film transistors.

The gate electrode of the pixel switch 2 is connected to a scanning line GL. One of the source electrode and the drain electrode of the pixel switch 2 is connected to a signal line SL, and the other is connected to the gate electrode of the drive transistor 3 and the capacitor 4. In the drive transistor 3, one of the source electrode and the drain electrode is connected to a power line PL and the capacitor 4, and the other is connected to the display element DE.

The configuration of the pixel circuit 1 is not limited to the example shown in the figure. For example, the pixel circuit 1 may comprise more thin-film transistors and capacitors.

The display element DE is an organic light-emitting diode (OLED) as a light-emitting element, and may be referred to as an organic EL element.

In the surrounding area SA, terminals for connecting an IC chip and a flexible printed circuit board are provided, which are not described in detail.

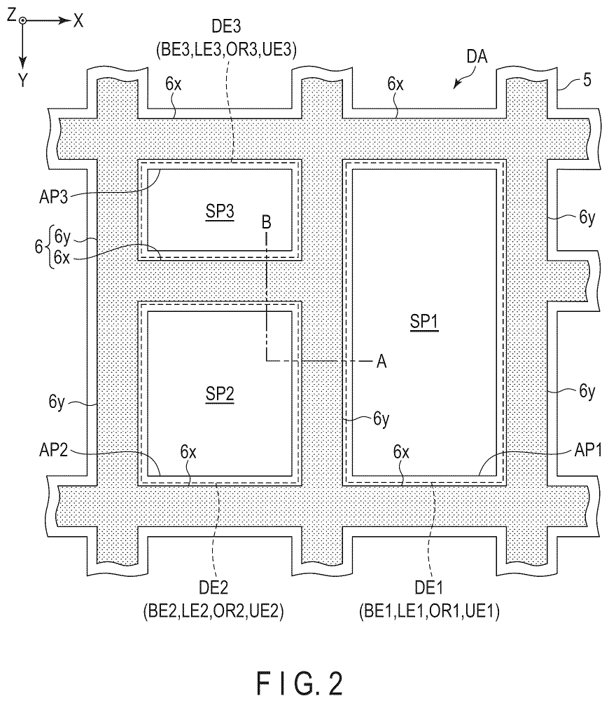

FIG. 2 is a diagram showing an example of the layout of the subpixels SP1, SP2, and SP3.

In the example of FIG. 2, the subpixel SP2 and the subpixel SP3 are arranged in the second direction Y. The subpixel SP1 and the subpixel SP2 are arranged in the first direction X, and the subpixel SP1 and the subpixel SP3 are arranged in the first direction X.

If the subpixels SP1, SP2, and SP3 have the above-described layout, a line of subpixels SP2 and SP3 disposed alternately in the second direction Y and a line of subpixels SP1 disposed in the second direction Y are formed in the display area DA. These lines are arranged alternately in the first direction X.

The layout of the subpixels SP1, SP2, and SP3 is not limited to the example of FIG. 2. As another example, the subpixels SP1, SP2, and SP3 in each of the pixels PX may be arranged in order in the first direction X.

In the display area DA, a rib 5 is disposed. The rib 5 comprises apertures AP1, AP2, and AP3 in the subpixels SP1, SP2, and SP3, respectively.

The subpixels SP1, SP2, and SP3 comprise display elements DE1, DE2, and DE3, respectively, as the display elements DE.

The display element DE1 comprises a base electrode BE1, a lower electrode LE1, an organic layer OR1, and an upper electrode UE1 each overlapping the aperture AP1 in plan view. The organic layer OR1 includes a light-emitting layer which emits light in the blue wavelength range. The base electrode BE1 and the lower electrode LE1 are electrically connected to each other.

The display element DE2 includes a base electrode BE2, a lower electrode LE2, an organic layer OR2, and an upper electrode UE2 each overlapping the aperture AP2 in plan view. The organic layer OR2 includes a light-emitting layer which emits light in the green wavelength range. The base electrode BE2 and the lower electrode LE2 are electrically connected to each other.

The display element DE3 includes a base electrode BE3, a lower electrode LE3, an organic layer OR3, and an upper electrode UE3 each overlapping the aperture AP3 in plan view. The organic layer OR3 includes a light-emitting layer which emits light in the red wavelength range. The base electrode BE3 and the lower electrode LE3 are electrically connected to each other.

A partition 6 is disposed at the boundaries between the subpixels SP1, SP2, and SP3. The partition 6 comprises first partitions 6x extending in the first direction X and second partitions 6y extending in the second direction Y. In the example of FIG. 2, the first partitions 6x and the second partitions 6y are connected to each other. The partition 6 as a whole is thereby formed into a latticed form surrounding the display elements DE1, DE2, and DE3. It is also possible to say that the partition 6 comprises an aperture in each of the subpixels SP1, SP2, and SP3.

In FIG. 2, the external shapes of the base electrodes BE1, BE2, and BE3, the external shapes of the lower electrodes LE1, LE2, and LE3, the external shapes of the organic layers OR1, OR2, and OR3, and the external shapes of the upper electrodes UE1, UE2, and UE3 are represented by broken lines; however, the respective external shapes of the base electrodes, the lower electrodes, the organic layers, and the upper electrodes do not necessarily reflect their exact shapes.

The respective peripheries of the base electrodes BE1, BE2, and BE3, the respective peripheries of the lower electrodes LE1, LE2, and LE3, the respective peripheries of the organic layers OR1, OR2, and OR3, and the respective peripheries of the upper electrodes UE1, UE2, and UE3 overlap the rib 5 in plan view.

The base electrodes BE1, BE2, and BE3 and the lower electrodes LE1, LE2, and LE3 correspond to, for example, the anodes of the display elements. The upper electrodes UE1, UE2, and UE3 correspond to the cathodes of the display elements or common electrodes.

The base electrode BE1 and the lower electrode LE1 are electrically connected to the pixel circuit 1 (see FIG. 1) of the subpixel SP1. The base electrode BE2 and the lower electrode LE2 are electrically connected to the pixel circuit 1 of the subpixel SP2. The base electrode BE3 and the lower electrode LE3 are electrically connected to the pixel circuit 1 of the subpixel SP3.

In the example of FIG. 2, the area of the aperture AP1 overlapping the base electrode BE1, the area of the aperture AP2 overlapping the base electrode BE2, and the area of the aperture AP3 overlapping the base electrode BE3 are different from each other. That is, the area of the aperture AP2 is smaller than the area of the aperture AP1, and the area of the aperture AP3 is smaller than the area of the aperture AP2. In other words, the area of the base electrode BE2 exposed through the aperture AP2 is smaller than the area of the base electrode BE1 exposed through the aperture AP1, and the area of the base electrode BE3 exposed through the aperture AP3 is smaller than the area of the base electrode BE2 exposed through the aperture AP2.

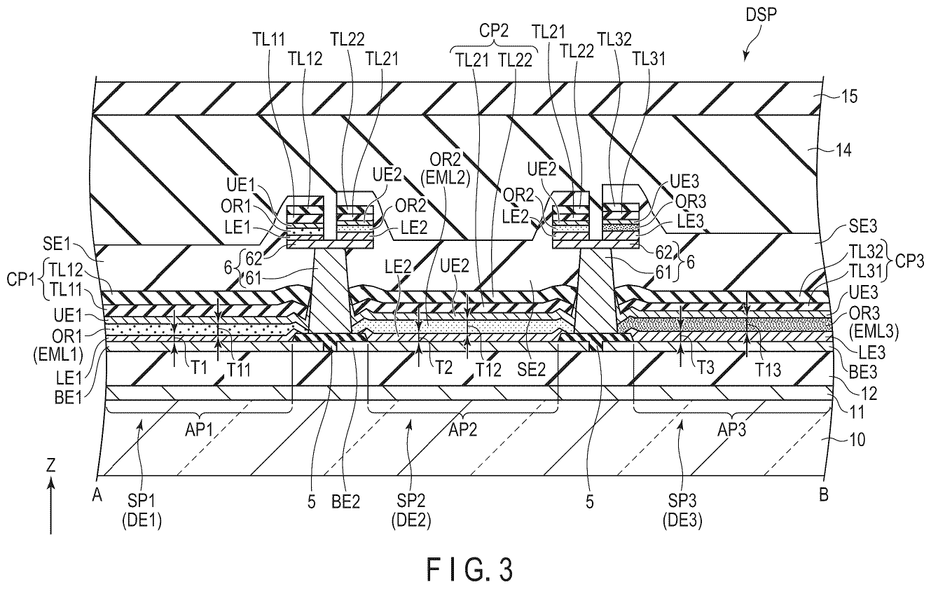

FIG. 3 is a cross-sectional view showing a configuration example of the display device DSP along line A-B in FIG. 2.

A circuit layer 11 is disposed on the substrate 10. The circuit layer 11 includes various circuits such as the pixel circuit 1 shown in FIG. 1 and various lines such as the scanning line GL, the signal line SL, and the power line PL. The circuit layer 11 is covered by an insulating layer 12. The insulating layer 12 is an organic insulating layer which planarizes irregularities caused by the circuit layer 11.

The base electrodes BE1, BE2, and BE3 are disposed on the insulating layer 12 and are separated from each other. The rib 5 is disposed on the insulating layer 12 and the base electrodes BE1, BE2, and BE3. The aperture AP1 of the rib 5 overlaps the base electrode BE1, the aperture AP2 overlaps the base electrode BE2, and the aperture AP3 overlaps the base electrode BE3. The peripheries of the base electrodes BE1, BE2, and BE3 are covered by the rib 5. Between the base electrodes adjacent to each other of the base electrodes BE1, BE2, and BE3, the insulating layer 12 is covered by the rib 5. The base electrodes BE1, BE2, and BE3 are connected to the respective pixel circuits 1 of the subpixels SP1, SP2, and SP3 through contact holes provided in the insulating layer 12.

The partition 6 includes a conductive lower part 61 disposed on the rib 5 and an upper part 62 disposed on the lower part 61. The upper part 62 has a width greater than that of the lower part 61. For this reason, in FIG. 3, both end portions of the upper part 62 project more than the side surfaces of the lower part 61. Such a shape of the partition 6 is referred to as an overhang form.

The lower electrode LE1 contacts the base electrode BE1 through the aperture AP1 and covers the base electrode BE1 exposed through the aperture AP1, and its periphery is located on the rib 5. The lower electrode LE1 is separated from the lower part 61. The organic layer OR1 contacts the upper surface of the lower electrode LE1 and covers the lower electrode LE1. The periphery of the organic layer OR1 is located outside the lower electrode LE1 and is located on the rib 5. The upper electrode UE1 covers the organic layer OR1 and contacts the lower part 61.

The lower electrode LE2 contacts the base electrode BE2 through the aperture AP2 and covers the base electrode BE2 exposed through the aperture AP2, and its periphery is located on the rib 5. The lower electrode LE2 is separated from the lower part 61. The organic layer OR2 contacts the upper surface of the lower electrode LE2 and covers the lower electrode LE2. The periphery of the organic layer OR2 is located outside the lower electrode LE2 and is located on the rib 5. The upper electrode UE2 covers the organic layer OR2 and contacts the lower part 61.

The lower electrode LE3 contacts the base electrode BE3 through the aperture AP3 and covers the base electrode BE3 exposed through the aperture AP3, and its periphery is located on the rib 5. The lower electrode LE3 is separated from the lower part 61. The organic layer OR3 contacts the upper surface of the lower electrode LE3 and covers the lower electrode LE3. The periphery of the organic layer OR3 is located outside the lower electrode LE3 and is located on the rib 5. The upper electrode UE3 covers the organic layer OR3 and contacts the lower part 61.

In the example of FIG. 3, the subpixel SP1 comprises a cap layer CP1 and a sealing layer SE1, the subpixel SP2 comprises a cap layer CP2 and a sealing layer SE2, and the subpixel SP3 comprises a cap layer CP3 and a sealing layer SE3. The cap layers CP1, CP2, and CP3 function as optical adjustment layers which improve the extraction efficiency of light emitted from the organic layers OR1, OR2, and OR3, respectively.

The cap layer CP1 comprises a transparent layer TL11 disposed on the upper electrode UE1 and a transparent layer TL12 disposed on the transparent layer TL11. The refractive index of the transparent layer TL12 is smaller than the refractive index of the transparent layer TL11.

The cap layer CP2 comprises a transparent layer TL21 disposed on the upper electrode UE2 and a transparent layer TL22 disposed on the transparent layer TL21. The refractive index of the transparent layer TL22 is smaller than the refractive index of the transparent layer TL21.

The cap layer CP3 comprises a transparent layer TL31 disposed on the upper electrode UE3 and a transparent layer TL32 disposed on the transparent layer TL31. The refractive index of the transparent layer TL32 is smaller than the refractive index of the transparent layer TL31.

In this manner, the transparent layers TL11, TL21, and TL31 correspond to high-refractive-index layers of the cap layers. In contrast, the transparent layers TL12, TL22, and TL32 correspond to low-refractive-index layers of the cap layers. The cap layers CP1, CP2, and CP3 may be a stacked layer body of three or more layers. In addition, the cap layers CP1, CP2, and CP3 may be omitted.

The sealing layer SE1 is disposed on the transparent layer TL12 and contacts the partition 6. That is, the sealing layer SE1 continuously covers the display element DE1 including the lower electrode LE1, the organic layer OR1, the upper electrode UE1, and the cap layer CP1, and the partition 6 around the display element DE1. For example, the refractive index of the sealing layer SE1 is greater than the refractive index of the transparent layer TL12.

The sealing layer SE2 is disposed on the transparent layer TL22 and contacts the partition 6. That is, the sealing layer SE2 continuously covers the display element DE2 including the lower electrode LE2, the organic layer OR2, the upper electrode UE2, and the cap layer CP2, and the partition 6 around the display element DE2. For example, the refractive index of the sealing layer SE2 is greater than the refractive index of the transparent layer TL22.

The sealing layer SE3 is disposed on the transparent layer TL32 and contacts the partition 6. That is, the sealing layer SE3 continuously covers the display element DE3 including the lower electrode LE3, the organic layer OR3, the upper electrode UE3, and the cap layer CP3, and the partition 6 around the display element DE3. For example, the refractive index of the sealing layer SE3 is greater than the refractive index of the transparent layer TL32.

In the example of FIG. 3, portions of the lower electrode LE1, the organic layer OR1, the upper electrode UE1, and the cap layer CP1 are located on the partition 6 around the subpixel SP1. These portions are separated from the portions located at the aperture AP1 (portions constituting the display element DE1) of the lower electrode LE1, the organic layer OR1, the upper electrode UE1, and the cap layer CP1. Similarly, portions of the lower electrode LE2, the organic layer OR2, the upper electrode UE2, and the cap layer CP2 are located on the partition 6 around the subpixel SP2, and these portions are separated from the portions located at the aperture AP2 (portions constituting the display element DE2) of the lower electrode LE2, the organic layer OR2, the upper electrode UE2, and the cap layer CP2. In addition, portions of the lower electrode LE3, the organic layer OR3, the upper electrode UE3, and the cap layer CP3 are located on the partition 6 around the subpixel SP3, and these portions are separated from the portions located at the aperture AP3 (portions constituting the display element DE3) of the lower electrode LE3, the organic layer OR3, the upper electrode UE3, and the cap layer CP3.

End portions of the sealing layers SE1, SE2, and SE3 are located on the partition 6. In the example of FIG. 3, the end portions of the sealing layers SE1 and SE2 located on the partition 6 between the subpixels SP1 and SP2 are separated from each other, and the end portions of the sealing layers SE2 and SE3 located on the partition 6 between the subpixels SP2 and SP3 are separated from each other.

The sealing layers SE1, SE2, and SE3 are covered by a resin layer 14. The resin layer 14 is covered by a sealing layer 15. A resin layer may be further disposed on the sealing layer 15.

The rib 5, the sealing layers SE1, SE2, and SE3, and the sealing layer 15 are formed of an inorganic insulating material, for example, silicon nitride (SiNx). The rib 5, the sealing layers SE1, SE2, and SE3, and the sealing layer 15 may be formed of another inorganic insulating material such as silicon oxide (SiOx), silicon oxynitride (SiON), or aluminum oxide (Al₂O₃).

The organic layer OR1 includes a light-emitting layer EML1. The organic layer OR2 includes a light-emitting layer EML2. The organic layer OR3 includes a light-emitting layer EML3. The light-emitting layer EML1, the light-emitting layer EML2, and the light-emitting layer EML3 are formed of materials different from each other. For example, the light-emitting layer EML1 is formed of a material which emits light in the blue wavelength range (first color), the light-emitting layer EML2 is formed of a material which emits light in the green wavelength range (second color), and the light-emitting layer EML3 is formed of a material which emits light in the red wavelength range (third color).

The upper electrodes UE1, UE2, and UE3 are formed of a metal material, for example, an alloy of magnesium and silver (MgAg).

The lower part 61 of the partition 6 is formed of, for example, aluminum (Al). The lower part 61 may be formed of an aluminum alloy such as aluminum-neodymium (AlNd) or may have a multilayered structure of an aluminum layer and an aluminum-alloy layer. Moreover, the lower part 61 may comprise a thin film formed of a metal material different from aluminum and an aluminum alloy under the aluminum layer or the aluminum-alloy layer. The thin film can be formed of, for example, molybdenum (Mo).

The upper part 62 of the partition 6 has, for example, a multilayered structure of a thin film formed of a metal material such as titanium (Ti) and a thin film formed of a conductive oxide such as ITO. The upper part 62 may have a single-layer structure of a metal material such as titanium. A common voltage is applied to the partition 6. The common voltage is applied to each of the upper electrodes UE1, UE2, and UE3, which contact the side surfaces of the lower part 61.

The base electrodes BE1, BE2, and BE3 are metal electrodes formed of a first metal material and do not include an oxide conductive layer such as indium tin oxide (ITO). The first metal material is aluminum or an aluminum alloy.

The lower electrodes LE1, LE2, and LE3 are metal electrodes formed of a second metal material different from the first metal material and do not include an oxide conductive layer such as ITO. The second metal material is silver.

That is, in the aperture AP1, no oxide conductive layer exists directly under the organic layer OR1. In addition, the stacked layer body of the base electrode BE1 and the lower electrode LE1 formed of different types of metal functions as a reflecting electrode which reflects light emitted from the light-emitting layer EML1 of the organic layer OR1.

Similarly, in the aperture AP2, no oxide conductive layer exists directly under the organic layer OR2. In addition, the stacked layer body of the base electrode BE2 and the lower electrode LE2 formed of different types of metal functions as a reflecting electrode which reflects light emitted from the light-emitting layer EML2 of the organic layer OR2.

Similarly, in the aperture AP3, no oxide conductive layer exists directly under the organic layer OR3. In addition, the stacked layer body of the base electrode BE3 and the lower electrode LE3 formed of different types of metal functions as a reflecting electrode which reflects light emitted from the light-emitting layer EML3 of the organic layer OR3.

The thickness (distance along a normal of the substrate 10 between the base electrode BE1 and the organic layer OR1) T1 of the lower electrode LE1 in the aperture AP1, the thickness (distance along the normal of the substrate 10 between the base electrode BE2 and the organic layer OR2) T2 of the lower electrode LE2 in the aperture AP2, and the thickness (distance along the normal of the substrate 10 between the base electrode BE3 and the organic layer OR3) T3 of the lower electrode LE3 in the aperture AP3 are different from each other.

For example, the thickness T2 is greater than the thickness T1, and the thickness T3 is greater than the thickness T2. The thickness T3 may be equal to the thickness T2 (T1<T2≤T3).

In the above-described display device, when a potential difference is formed between the lower electrode LE1 and the upper electrode UE1, the light-emitting layer EML1 of the organic layer OR1 emits light in the blue wavelength range. When a potential difference is formed between the lower electrode LE2 and the upper electrode UE2, the light-emitting layer EML2 of the organic layer OR2 emits light in the green wavelength range. When a potential difference is formed between the lower electrode LE3 and the upper electrode UE3, the light-emitting layer EML3 of the organic layer OR3 emits light in the red wavelength range.

Blue light which proceeds toward the lower electrode LE1 of the blue light from the light-emitting layer EML1 is reflected by the reflecting electrode which is the stacked layer body of the base electrode BE1 and the lower electrode LE1. At this time, since no ITO layer exists between the organic layer OR1 and the reflecting electrode, the undesirable absorption of blue light by an ITO layer is suppressed. In particular, because the light absorption index of an ITO layer is high in the blue wavelength range, the loss of blue light is large. Accordingly, the luminous efficacy can be improved. The luminous efficacy here corresponds to the luminance per unit current (current-luminance efficacy) in the frontal direction of the display device DSP.

Green light which proceeds toward the lower electrode LE2 of the green light from the light-emitting layer EML2 is reflected by the reflecting electrode which is the stacked layer body of the base electrode BE2 and the lower electrode LE2. At this time, since no ITO layer exists between the organic layer OR2 and the reflecting electrode, the undesirable absorption of green light by an ITO layer is suppressed.

Red light which proceeds toward the lower electrode LE3 of the red light from the light-emitting layer EML3 is reflected by the reflecting electrode which is the stacked layer body of the base electrode BE3 and the lower electrode LE3. At this time, since no ITO layer exists between the organic layer OR3 and the reflecting electrode, the undesirable absorption of red light by an ITO layer is suppressed.

The relationship between the thicknesses of the base electrodes and the lower electrodes and reflectance will be described next.

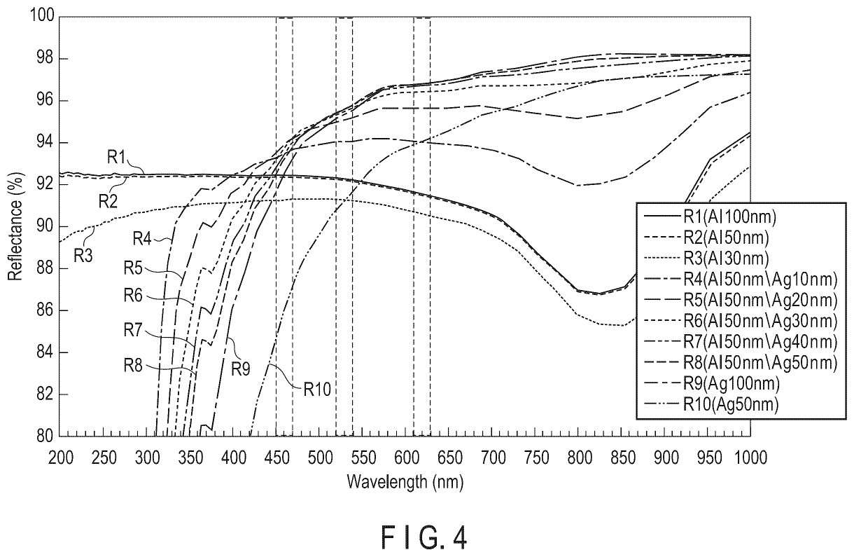

FIG. 4 is a diagram showing simulation results of reflectance.

The horizontal axis represents wavelength (nm) and the vertical axis represents reflectance (%).
R1 in the figure represents a result in the case in which a silver layer is omitted and an aluminum layer having a thickness of 100 nm is located on an inorganic insulating layer.
R2 in the figure represents a result in the case in which a silver layer is omitted and an aluminum layer having a thickness of 50 nm is located on an inorganic insulating layer.
R3 in the figure represents a result in the case in which a silver layer is omitted and an aluminum layer having a thickness of 30 nm is located on an inorganic insulating layer.
R4 in the figure represents a result in the case in which an aluminum layer having a thickness of 50 nm is located on an inorganic insulating layer and a silver layer having a thickness of 10 nm is located on the aluminum layer.
R5 in the figure represents a result in the case in which an aluminum layer having a thickness of 50 nm is located on an inorganic insulating layer and a silver layer having a thickness of 20 nm is located on the aluminum layer.
R6 in the figure represents a result in the case in which an aluminum layer having a thickness of 50 nm is located on an inorganic insulating layer and a silver layer having a thickness of 30 nm is located on the aluminum layer.
R7 in the figure represents a result in the case in which an aluminum layer having a thickness of 50 nm is located on an inorganic insulating layer and a silver layer having a thickness of 40 nm is located on the aluminum layer.
R8 in the figure represents a result in the case in which an aluminum layer having a thickness of 50 nm is located on an inorganic insulating layer and a silver layer having a thickness of 50 nm is located on the aluminum layer.
R9 in the figure represents a result in the case in which a silver layer having a thickness of 100 nm is located on an inorganic insulating layer and an aluminum layer is omitted.
R10 in the figure represents a result in the case in which a silver layer having a thickness of 50 nm is located on an inorganic insulating layer and an aluminum layer is omitted.

The inorganic insulating layers here are silicon oxide layers. In addition, the surfaces of the uppermost aluminum or silver layers are exposed to air.

For example, the blue wavelength range (first color) of light emitted by the light-emitting layer EML1 is 450 nm to 470 nm, and its center wavelength (peak) is 460 nm.

The green wavelength range (second color) of light emitted by the light-emitting layer EML2 is 520 nm to 540 nm, and its center wavelength (peak) is 530 nm.

The red wavelength range (third color) of light emitted by the light-emitting layer EML3 is 610 nm to 630 nm, and its center wavelength (peak) is 620 nm.

In the case of an aluminum single layer, it has been confirmed that when the thickness of the aluminum layer is 100 nm (R1) and 50 nm (R2), high reflectance is obtained compared to the reflectance obtained when the thickness of the aluminum layer is 30 nm (R3). In addition, it also has been confirmed that when the thickness is greater than or equal to 50 nm, substantially equal reflectance is obtained. Accordingly, if an aluminum layer is applied as a base electrode, it is preferable that the thickness of the base electrode be greater than or equal to 50 nm.

In the case of a silver single layer, it has been confirmed that when the thickness of the silver layer is 100 nm (R9) and 50 nm (R10), the reflectance in the blue wavelength range is low.

In the case of a stacked layer body of an aluminum layer and a silver layer, it has been confirmed that in all cases (R4 to R8), high reflectance is obtained in each of the blue wavelength range, the green wavelength range, and the red wavelength range, compared to the reflectance obtained in the case of an aluminum single layer or a silver single layer. Accordingly, when a stacked layer body of a base electrode (aluminum layer) and a lower electrode (silver layer) is applied as a reflecting electrode, it is preferable that the thickness of the lower electrode be greater than or equal to 10 nm.

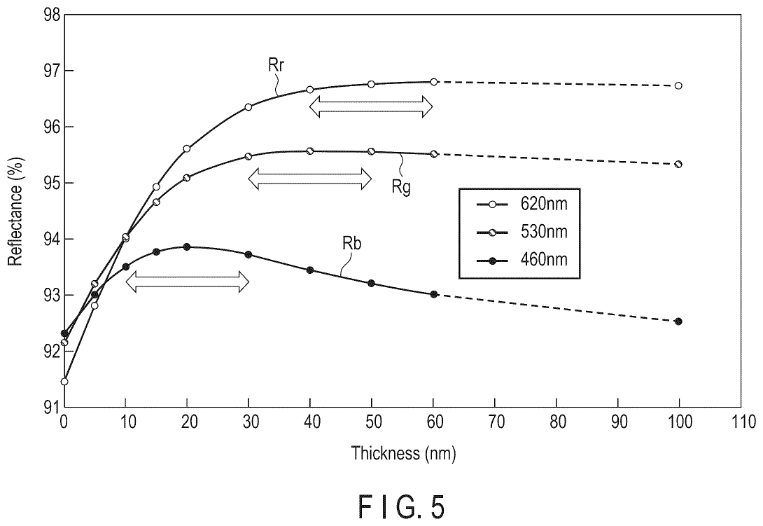

FIG. 5 is a diagram in which the results shown in FIG. 4 are grouped according to wavelength range.

The horizontal axis represents the thickness (nm) of a silver layer disposed on an aluminum layer having a thickness of 50 nm.

The vertical axis represents reflectance (%).

The case in which the thickness of the horizontal axis is 0 nm corresponds to the case in which a silver layer is omitted and an aluminum single layer has a thickness of 50 nm. In addition, the case in which the thickness of the horizontal axis is 100 nm corresponds to the case in which an aluminum layer is omitted and a silver single layer has a thickness of 100 nm.

Regarding the reflectance Rb of the center wavelength (460 nm) of the blue wavelength range, it has been confirmed that high reflectance is obtained when the thickness of the silver layer is greater than or equal to 10 nm but less than or equal to 30 nm. In the stacked layer body of the base electrode (aluminum layer) BE1 and the lower electrode (silver layer) LE1, the thickness of the lower electrode LE1 is smaller than the thickness of the base electrode BE1.

Regarding the reflectance Rg of the center wavelength (530 nm) of the green wavelength range, it has been confirmed that high reflectance is obtained when the thickness of the silver layer is greater than or equal to 30 nm. In order to improve the efficiency in the manufacturing process, it is preferable that the thickness of the silver layer be less than equal to 50 nm. In the stacked layer body of the base electrode (aluminum layer) BE2 and the lower electrode (silver layer) LE2, the thickness of the lower electrode LE2 is equal to the thickness of the base electrode BE2 or smaller than the thickness of the base electrode BE2.

Regarding the reflectance Rr of the center wavelength (620 nm) of the red wavelength range, it has been confirmed that high reflectance is obtained when the thickness of the silver layer is greater than or equal to 40 nm. In order to improve the efficiency in the manufacturing process, it is preferable that the thickness of the silver layer be less than or equal to 60 nm.

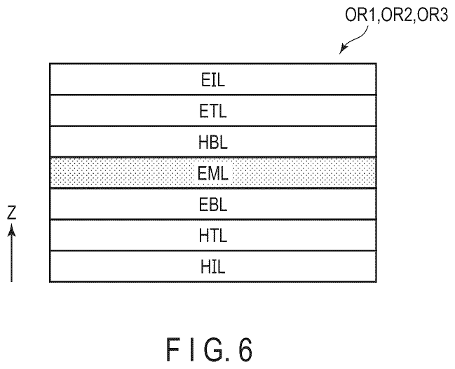

FIG. 6 is a diagram showing an example of a layered structure which can be applied to the organic layers OR1, OR2, and OR3.

The organic layers OR1, OR2, and OR3 have, for example, the structure in which a hole-injection layer HIL, a hole-transport layer HTL, an electron-blocking layer EBL, a light-emitting layer EML, a hole-blocking layer HBL, an electron-transport layer ETL, and an electron-injection layer EIL are stacked in order in the third direction Z. The organic layers OR1, OR2, and OR3 may have a so-called tandem structure including light-emitting layers EML.

In order to increase the light extraction efficiency of the display elements DE1, DE2, and DE3, it is preferable that the thicknesses of the organic layers OR1, OR2, and OR3 be adjusted in accordance with the wavelength of light emitted by the light-emitting layer EML. For example, the thickness T11 of the organic layer OR1, the thickness T12 of the organic layer OR2, and the thickness T13 of the organic layer OR3 shown in FIG. 3 are different from each other. To be specific, the thickness T12 is greater than the thickness T11, and the thickness T13 is greater than the thickness T12 (T11<T12<T13). The difference between the thicknesses T11, T12, and T13 like this is caused by, for example, the difference in thickness of the respective hole-transport layers HTL of the organic layers OR1, OR2, and OR3, but is not limited to this example.

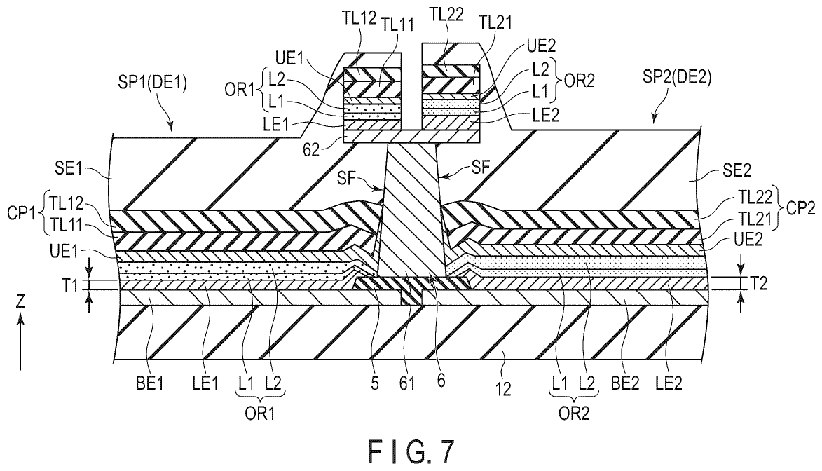

FIG. 7 is a schematic cross-sectional view showing the partition 6 between the subpixel SP1 and the subpixel SP2 and its vicinity in an enlarged manner. In FIG. 7, the illustration of the resin layer 14 and the sealing layer 15 is omitted.

The lower part 61 comprises a pair of side surfaces SF. The upper part 62 projects more in the width direction of the partition 6 than the side surfaces SF. The width direction of the partition 6 corresponds to the second direction Y in the case of the first partitions 6x shown in FIG. 2, and corresponds to the first direction X in the case of the second partitions 6y.

The thickness of the lower electrode LE1, directly under the upper part 62, decreases toward the side surface SF. The end portion of the lower electrode LE1 is separated from the side surface SF.

The organic layer OR1 covers the whole lower electrode LE1. Between the lower electrode LE1 and the lower part 61, the organic layer OR1 contacts the rib 5.

The organic layer OR1 comprises a first layer L1 and a second layer L2 covering the first layer L1. Of the layers shown in FIG. 6, at least the hole-injection layer HIL is included in the first layer L1 and the layers not included in the first layer L1 are included in the second layer L2. For example, the first layer L1 is constituted of the hole-injection layer HIL, and the second layer L2 is constituted of the hole-transport layer HTL, the electron-blocking layer EBL, the light-emitting layer EML, the hole-blocking layer HBL, the electron-transport layer ETL, and the electron-injection layer EIL.

In the example of FIG. 7, the second layer L2 contacts the lower part 61, while the first layer L1 does not contact the lower part 61. If the hole-injection layer HIL included in the first layer L1 contacts the lower part 61, it can be an undesirable current leak path. Since the first layer L1 is separated from the lower part 61, an undesirable current leak through the hole-injection layer HIL included in the first layer L1 is suppressed. As another example, both the first layer L1 and the second layer L2 may be separated from the lower part 61.

The upper electrode UE1 covers the second layer L2 of the organic layer OR1 as a whole. Moreover, the upper electrode UE1 contacts the side surface SF. In the example of FIG. 7, the upper electrode UE1 is separated from the rib 5. If both the first layer L1 and the second layer L2 are separated from the lower part 61, the upper electrode UE1 may contact the rib 5.

Of the side surface SF facing the subpixel SP1, the area not covered by the upper electrode UE1 is covered by the sealing layer SE1. The sealing layer SE1 covers the lower surface of the upper part 62 and also covers the stacked layer body of the lower electrode LE1, the first layer L1, the second layer L2, the upper electrode UE1, the transparent layer TL11, and the transparent layer TL12 disposed on the upper part 62.

The configuration of the base electrode BE2, the lower electrode LE2, the organic layer OR2, the upper electrode UE2, the cap layer CP2, and the sealing layer SE2 shown in FIG. 7 is the same as the configuration of the base electrode BE1, the lower electrode LE1, the organic layer OR1, the upper electrode UE1, the cap layer CP1, and the sealing layer SE1. In addition, the configuration of the base electrode BE3, the lower electrode LE3, the organic layer OR3, the upper electrode UE3, the cap layer CP3, and the sealing layer SE3 is also the same as the configuration of the base electrode BE1, the lower electrode LE1, the organic layer OR1, the upper electrode UE1, the cap layer CP1, and the sealing layer SE1.

A manufacturing method of the display device DSP will be described next.

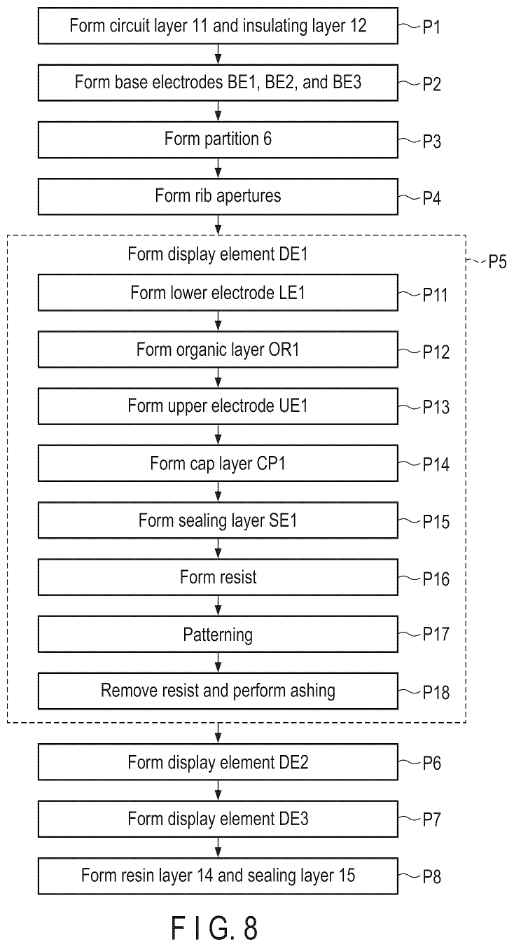

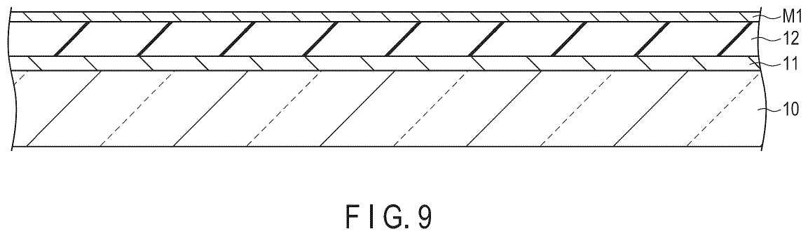

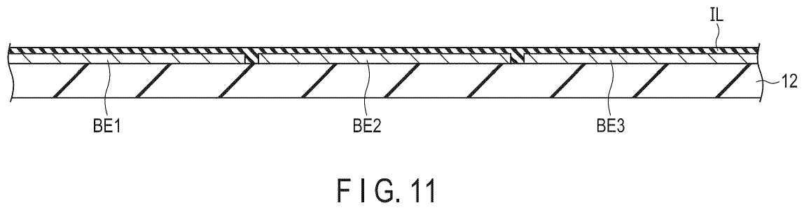

FIG. 8 is a flowchart showing an example of the manufacturing method of the display device DSP. FIG. 9 to FIG. 19 are schematic cross-sectional view each showing part of the manufacturing process of the display device DSP. In FIG. 11 to FIG. 19, the substrate 10 and the circuit layer 11 are omitted.

In manufacturing the display device DSP, first, the circuit layer 11 and the insulating layer 12 are formed on the substrate 10 (step P1).

Then, the base electrodes BE1, BE2, and BE3 are formed on the insulating layer 12 (step P2). To be specific, as shown in FIG. 9, a metal layer Ml is formed of a first metal material on the insulating layer 12. The first metal material is, for example, aluminum.

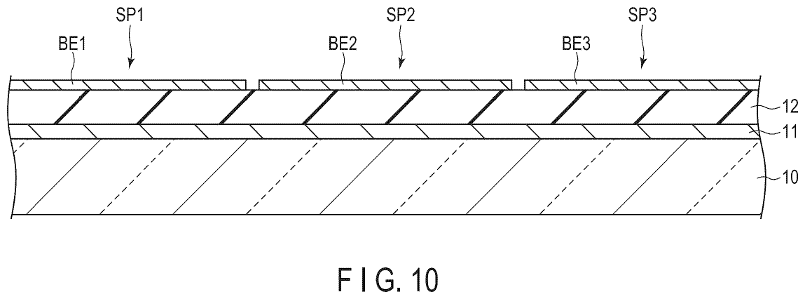

Then, as shown in FIG. 10, the metal layer Ml is patterned, and the base electrodes BE1, BE2, and BE3, separated from each other, are formed. The base electrode BE1 is located in the subpixel SP1, the base electrode BE2 is located in the subpixel SP2, and the base electrode BE3 is located in the subpixel SP3. The patterning here includes the step of forming a resist having a predetermined shape on the metal layer Ml, the step of performing dry etching with the resist used as a mask and thereby removing part of the metal layer Ml, and the step of removing the resist.

Then, the partition 6 is formed on the rib 5 (step P3), and the apertures AP1, AP2, and AP3 of the rib 5 are formed (step P4). Specific steps are as follows.

First, as shown in FIG. 11, an inorganic insulating layer IL is formed on the insulating layer 12 and the base electrodes BE1, BE2, and BE3. The inorganic insulating layer IL is, for example, formed of silicon oxynitride (SiON) by chemical vapor deposition (CVD).

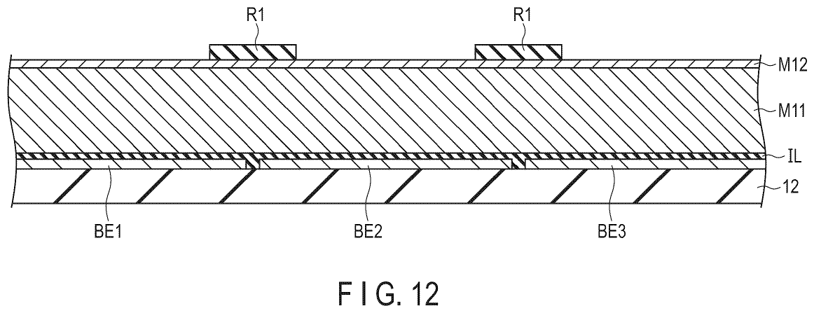

Then, as shown in FIG. 12, a metal layer M11 which is a base of the lower part 61 is formed on the inorganic insulating layer IL, and a thin film M12 which is a base of the upper part 62 is formed on the metal layer M11. Moreover, a resist R1 corresponding to the shape of the partition 6 is formed on the thin film M12.

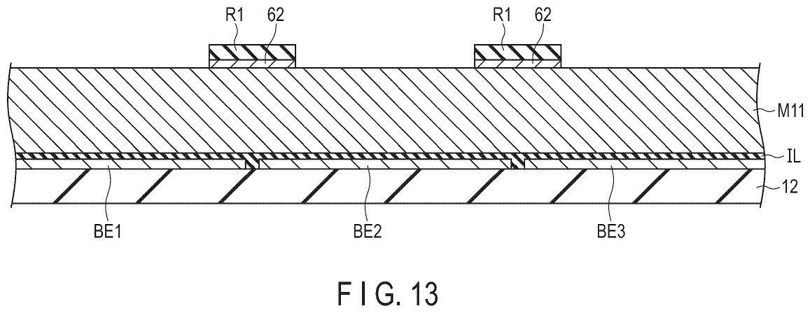

Then, as shown in FIG. 13, the portions exposed through the resist R1 of the thin film M12 are removed by wet etching. The upper part 62 is thereby formed.

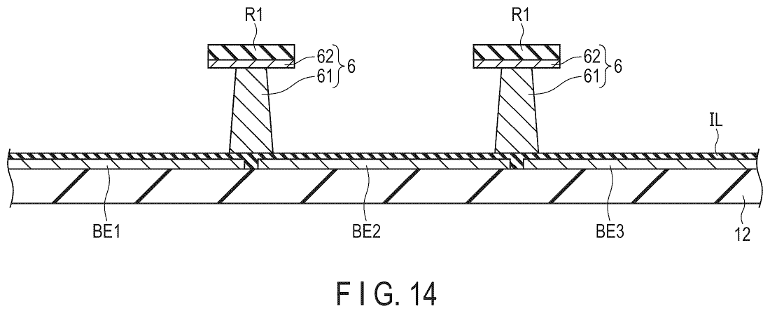

Then, as shown in FIG. 14, anisotropic dry etching and isotropic wet etching are performed, and the portions exposed through the resist R1 of the metal layer M11 are removed. The lower part 61 is thereby formed. After the lower part 61 is formed, the resist R1 is removed, and the partition 6 in an overhang form is completed.

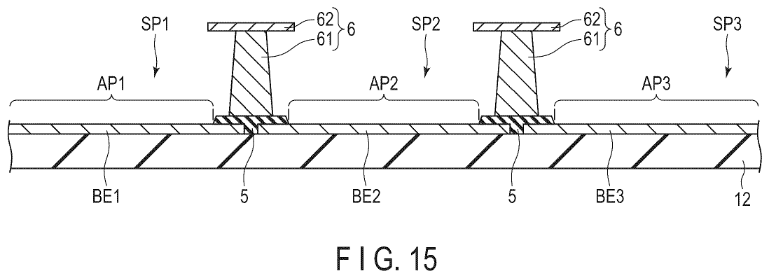

After step P3, as shown in FIG. 15, the aperture AP1 overlapping the base electrode BE1, the aperture AP2 overlapping the base electrode BE2, and the aperture AP3 overlapping the base electrode BE3 are formed. For example, anisotropic dry etching is performed using the upper part 62 of the partition 6, and the inorganic insulating layer IL is removed. The rib 5 comprising the apertures AP1, AP2, and AP3 is thereby formed. As another example, it is also possible to, after forming a resist which individually covers the partition 6, perform anisotropic dry etching to remove the portions exposed through the resist of the inorganic insulating layer IL, and then remove the resist, thereby forming the rib 5 comprising the apertures AP1, AP2, and AP3.

The partition 6 may be formed after the apertures AP1, AP2, and AP3 of the rib 5 are formed.

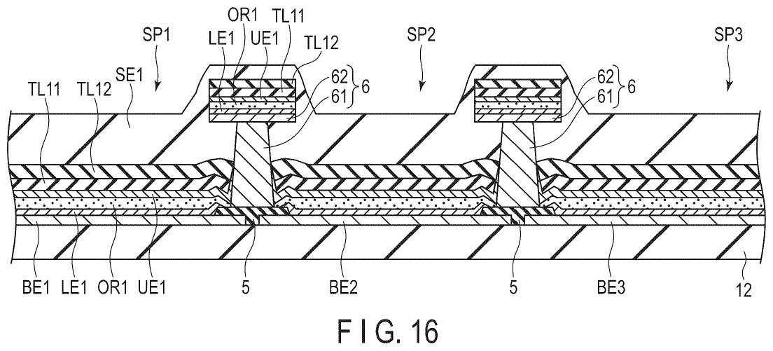

After step P4, the display element DE1 is formed (step P5). To be specific, as shown in FIG. 16, the lower electrode LE1 is formed by depositing the second metal material on the base electrodes BE1, BE2 and BE3 and the partition 6 (step P11). The second metal material is silver.

Then, the organic layer OR1 is formed by depositing the materials for forming the hole-injection layer, the hole-transport layer, the electron-blocking layer, the light-emitting layer, the hole-blocking layer, the electron-transport layer, the electron-injection layer, etc., on the lower electrode LE1 in series (step P12).

Then, the upper electrode UE1 is formed by depositing a mixture of magnesium and silver on the organic layer OR1 (step P13).

Then, the transparent layer TL11 is formed by depositing a high-refractive-index material on the upper electrode UE1. Further, the transparent layer TL12 is formed by depositing a low-refractive-index material on the transparent layer TL11. In this manner, the cap layer CP1 is formed (process P14). Further, the sealing layer SE1 is formed so as to cover the transparent layer TL12 and the partition 6 (process P15). The sealing layer SE1 is formed of silicon nitride (SiN) by a CVD.

The lower electrode LE1, the organic layer OR1, the upper electrode UE1, the transparent layer TL11, the transparent layer TL12, and the sealing layer SE1 are formed at least over the whole display area DA, and are disposed not only in the subpixel SP1 but also in the subpixels SP2 and SP3. The lower electrode LE1, the organic layer OR1, the upper electrode UE1, the transparent layer TL11, and the transparent layer TL12 are divided by the partition 6 in an overhang form. The lower electrode LE1 is separated from the lower part 61 and the upper electrode UE1 contacts a side surface of the lower part 61. The sealing layer SE1 continuously covers the display element DE1 including the lower electrode LE1, the organic layer OR1, the upper electrode UE1, the transparent layer TL11, and the transparent layer TL12, and the partition 6.

When the lower electrode LE1, the organic layer OR1, the upper electrode UE1, the transparent layer TL11, and the transparent layer TL12 are each formed by vapor deposition, a material emitted from an evaporation source is blocked by the upper part 62. For this reason, on the upper part 62, respective portions of the lower electrode LE1, the organic layer OR1, the upper electrode UE1, the transparent layer TL11, and the transparent layer TL12 are stacked.

At least steps P11 and P12, preferably steps P11 to P15, are continuously performed in a vacuum environment. That is, at least from the start of step P11 to the completion of step P12, the surroundings of the substrates to be processed in these steps are continuously kept in a vacuum. Accordingly, the lower electrode LE1 formed in step P11 is covered by the lowermost layer (for example, the hole-injection layer HIL) of the organic layer OR1 in step P12 without being exposed to an atmosphere.

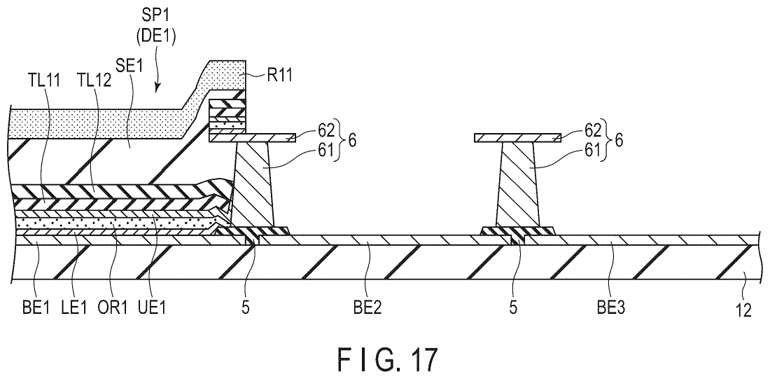

After step P15, as shown in FIG. 17, a resist R11 is disposed on the sealing layer SE1 (step P16). The resist R11 covers the subpixel SP1 and part of the partition 6 around the subpixel SP1. Then, with the resist R11 used as a mask, the lower electrode LE1, the organic layer OR1, the upper electrode UE1, the transparent layer TL11, the transparent layer TL12, and the sealing layer SE1 are patterned (step P17). This patterning step includes performing dry etching and wet etching, thereby removing the portions exposed through the resist R11 of the lower electrode LE1, the organic layer OR1, the upper electrode UE1, the transparent layer TL11, the transparent layer TL12, and the sealing layer SE1 sequentially.

After step P17, the resist R11 is removed by a stripping solution, and a residue of the resist R11, etc., is removed by asking (step P18). In this way, the display element DE1 and the sealing layer SE1 are formed in the subpixel SP1, and the base electrode BE2 of the subpixel SP2 and the base electrode BE3 of the subpixel SP3 are exposed.

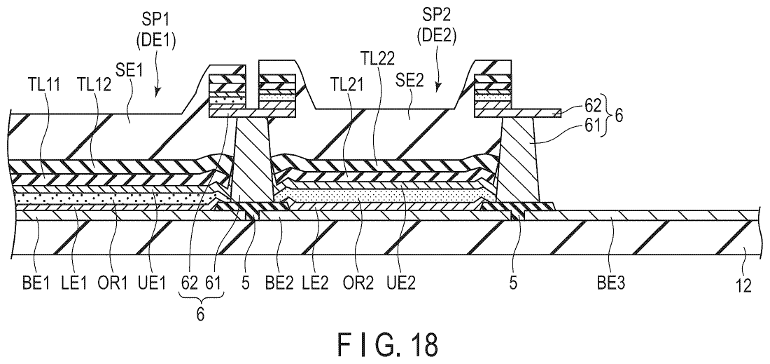

After the formation of the display element DE1, the display element DE2 is formed as shown in FIG. 18 (step P6). The procedure for forming the display element DE2 is the same as steps P11 to P18. That is, in the same way as in steps P11 to P15, the lower electrode LE2, the organic layer OR2, the upper electrode UE2, the transparent layer TL21, and the transparent layer TL22 are formed in order on the base electrode BE2 by vapor deposition, and the sealing layer SE2 is formed by CVD. Since at least the lower electrode LE2 and the organic layer OR2 are continuously formed in a vacuum environment, the lower electrode LE2 is covered by the organic layer OR2 without being exposed to an atmosphere.

Then, a resist is disposed on the sealing layer SE2 as in step P16, and the lower electrode LE2, the organic layer OR2, the upper electrode UE2, the transparent layer TL21, the transparent layer TL22, and the sealing layer SE2 are patterned as in step P17. After the patterning, the resist is removed as in step P18.

Through the above steps, the display element DE2 and the sealing layer SE2 are formed in the subpixel SP2, and the base electrode BE3 of the subpixel SP3 is exposed.

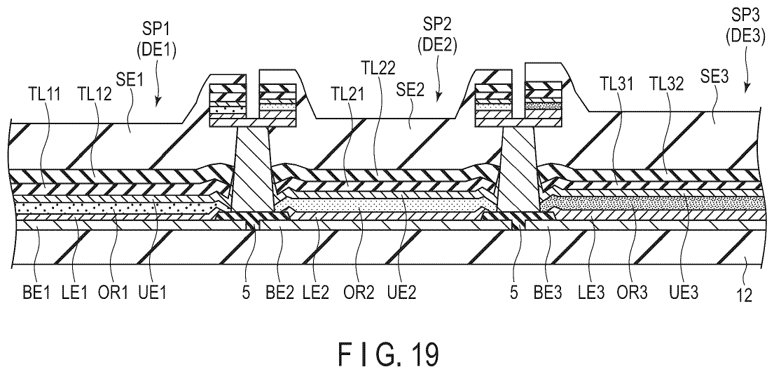

After the formation of the display element DE2, the display element DE3 is formed as shown in FIG. 19 (step P7). The procedure for forming the display element DE3 is the same as steps P11 to P18. That is, in the same way as in steps P11 to P15, the lower electrode LE3, the organic layer OR3, the upper electrode UE3, the transparent layer TL31, and the transparent layer TL32 are formed in order on the base electrode BE3 by vapor deposition, and the sealing layer SE3 is formed by CVD. Since at least the lower electrode LE3 and the organic layer OR3 are continuously formed in a vacuum environment, the lower electrode LE3 is covered by the organic layer OR3 without being exposed to an atmosphere.

Then, a resist is disposed on the sealing layer SE3 as in step P16, and the lower electrode LE3, the organic layer OR3, the upper electrode UE3, the transparent layer TL31, the transparent layer TL32, and the sealing layer SE3 are patterned as in step P17. After the patterning, the resist is removed as in step P18.

Through the above steps, the display element DE3 and the sealing layer SE3 are formed in the subpixel SP3.

After step P7, the resin layer 14 and the sealing layer 15 shown in FIG. 3 are formed in order (step P8). The display device DSP is thereby completed. In the above-described manufacturing process, it has been assumed that the display element DE1 is formed first, the display element DE2 is formed next, and the display element DE3 is formed last; however, the formation order of the display elements DE1, DE2, and DE3 is not limited to this example.

According to the present embodiment, the lower electrode LE1 and the organic layer OR1 are formed by continuous vapor deposition in a vacuum environment. Similarly, the lower electrode LE2 and the organic layer OR2, and the lower electrode LE3 and the organic layer OR3 are also formed by continuous vapor deposition in a vacuum environment. In this case, the surfaces of the lower electrodes LE1, LE2, and LE3 are not exposed to an atmosphere or a chemical. Therefore, damage to the lower electrodes LE1, LE2, and LE3 is mitigated, and a decrease in reflectance as a reflecting electrode is suppressed.

In addition, since an ITO layer is omitted from between the lower electrode LE1 and the organic layer OR1, between the lower electrode LE2 and the organic layer OR2, and between the lower electrode LE3 and the organic layer OR3, the absorption of light emitted from the organic layers OR1, OR2, and OR3 is suppressed. Moreover, a change in quality of the upper surfaces of the lower electrodes LE1, LE2, and LE3 is suppressed, and thus, excellent hole-injection properties can be secured.

Accordingly, the luminous efficacy of the display elements DE1, DE2, and DE3 improves.

Another configuration example will be described next.

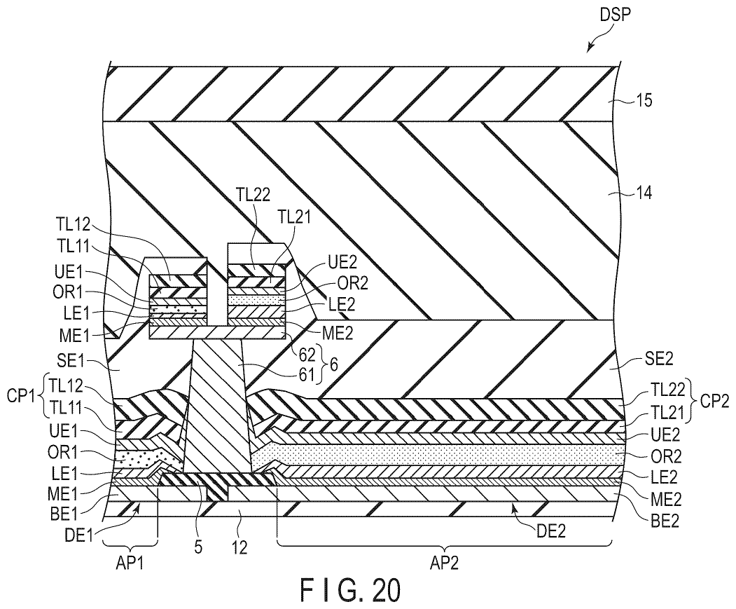

FIG. 20 is a cross-sectional view showing the other configuration example of the display device DSP. Respective parts of the display elements DE1 and DE2 are shown in the figure here.

The configuration example shown in FIG. 20 is different from the configuration example shown in FIG. 3 in that a middle electrode ME1 is interposed between the base electrode BE1 and the lower electrode LE1, and a middle electrode ME2 is interposed between the base electrode BE2 and the lower electrode LE2. In addition, in the display element DE3, too, a middle electrode is disposed between the base electrode BE3 and the lower electrode LE3. The following description focuses on main differences.

In the display element DE1, the middle electrode ME1 contacts the base electrode BE1 through the aperture AP1 and covers the base electrode BE1 exposed through the aperture AP1, and its periphery is located on the rib 5. The lower electrode LE1 overlaps the middle electrode ME1. The organic layer OR1 covers the stacked layer body of the middle electrode ME1 and the lower electrode LE1. The periphery of the organic layer OR1 is located outside the middle electrode ME1 and the lower electrode LE1, and is located on the rib 5. In the example shown in the figure, the periphery of the middle electrode ME1 and the periphery of the organic layer OR1 contact the rib 5. The upper electrode UE1 covers the organic layer OR1 and contacts the lower part 61.

In the display element DE2, the middle electrode ME2 contacts the base electrode BE2 through the aperture AP2 and covers the base electrode BE2 exposed through the aperture AP2, and its periphery is located on the rib 5. The lower electrode LE2 overlaps the middle electrode ME2. The organic layer OR2 covers the stacked layer body of the middle electrode ME2 and the lower electrode LE2. The periphery of the organic layer OR2 is located outside the middle electrode ME2 and the lower electrode LE2, and is located on the rib 5. In the example shown in the figure, the periphery of the middle electrode ME2 and the periphery of the organic layer OR2 contact the rib 5. The upper electrode UE2 covers the organic layer OR2 and contacts the lower part 61.

The middle electrodes ME1 and ME2 are metal electrodes formed of a third metal material different from the second metal material, and do not include an oxide conductive layer such indium tin oxide (ITO). The third metal material is aluminum or an aluminum alloy.

It is preferable that the respective thicknesses of the middle electrodes ME1 and ME2 be greater than or equal to 50 nm. Alternatively, it is preferable that the sum of the thicknesses of the base electrode BE1 and the middle electrode ME1 and the sum of the thicknesses of the base electrode BE2 and the middle electrode ME2 be greater than or equal to 50 nm.

In this configuration example, too, in the aperture AP1, an oxide conductive layer such as an ITO layer does not exist directly under the organic layer OR1. The stacked layer body of the base electrode BE1, the middle electrode ME1, and the lower electrode LE1 functions as a reflecting electrode which reflects light emitted from the light-emitting layer EML1 of the organic layer OR1.

Similarly, in the aperture AP2, no oxide conductive layer exists directly under the organic layer OR2. The stacked layer body of the base electrode BE2, the middle electrode ME2, and the lower electrode LE2 functions as a reflecting electrode which reflects light emitted from the light-emitting layer EML2 of the organic layer OR2.

A manufacturing method of the above-described display device DSP will be described next.

The manufacturing method described here is different from the manufacturing method in the above-described configuration example in that in step P5 shown in FIG. 8, the step of forming the middle electrode ME1 is added before the formation of the lower electrode LE1.

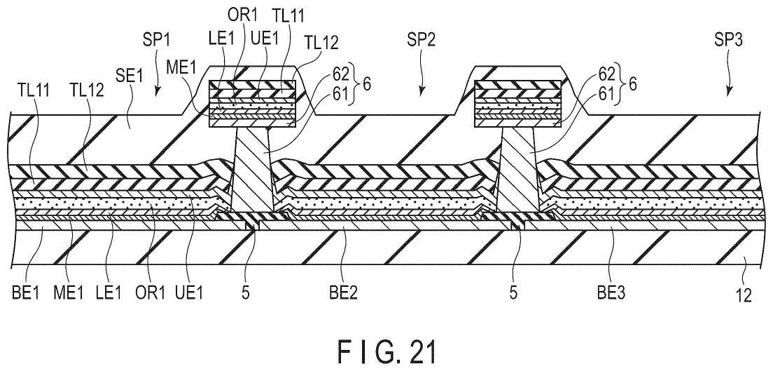

To be specific, as shown in FIG. 21, the middle electrode ME1 is formed by depositing a third metal material on the base electrodes BE1, BE2, and BE3 and the partition 6. The third metal material is aluminum. Then, the lower electrode LE1 is formed by depositing the second metal material on the middle electrode ME1 (step P11). The second metal material is silver.

Then, the organic layer OR1 is formed by depositing the materials for forming the hole-injection layer, the hole-transport layer, the electron-blocking layer, the light-emitting layer, the hole-blocking layer, the electron-transport layer, and the electron-injection layer, etc., on the lower electrode LE1 sequentially (step P12).

Then, the upper electrode UE1 is formed by depositing a mixture of magnesium and silver on the organic layer OR1 (step P13).

Then, the transparent layer TL11 is formed by depositing a high-refractive-index material on the upper electrode UE1. Further, the transparent layer TL12 is formed by depositing a low-refractive-index material on the transparent layer TL11. In this manner, the cap layer CP1 is formed (process P14). Further, the sealing layer SE1 is formed so as to cover the transparent layer TL12 and the partition 6 (process P15). The sealing layer SE1 is formed of silicon nitride (SiN) by a CVD.

Then, the resist R11 is disposed on the sealing layer SE1 (step P16). Then, with the resist R11 used as a mask, the lower electrode LE1, the organic layer OR1, the upper electrode UE1, the transparent layer TL11, the transparent layer TL12, and the sealing layer SE1 are patterned (step P17). Then, the resist R11 is removed (step P18).

Then, the display element DE2 is formed (step P6), and the display element DE3 is formed (step P7). Then, the resin layer 14 and the sealing layer 15 are formed in order (step P8). The display device DSP is thereby completed.

In this configuration example, the same advantages as those of the above-described configuration example are obtained. In addition, even if a base electrode is damaged during the manufacturing process, a decrease in reflectance of a reflecting electrode can be suppressed, since a middle electrode is formed of the same material as that of the base electrode immediately before a lower electrode is formed.

In the above-described embodiment, for example, the aperture AP1 corresponds to a first aperture, the aperture AP2 corresponds to a second aperture, the base electrode BE1 corresponds to a first base electrode, the base electrode BE2 corresponds to a second base electrode, the lower electrode LE1 corresponds to a first lower electrode, the lower electrode LE2 corresponds to a second lower electrode, the organic layer OR1 corresponds to a first organic layer, the organic layer OR2 corresponds to a second organic layer, the upper electrode UE1 corresponds to a first upper electrode, the upper electrode UE2 corresponds to a second upper electrode, the transparent layer TL11 corresponds to a first transparent layer, the transparent layer TL12 corresponds to a second transparent layer, the middle electrode ME1 corresponds to a first middle electrode, and the middle electrode ME2 corresponds to a second middle electrode.

All display devices and manufacturing methods thereof that are implementable with arbitrary changes in design by a person of ordinary skill in the art, based on the display devices and the manufacturing methods described above as the embodiments of the present invention, also belong to the scope of the present invention as long as they encompass the spirit of the present invention.

Various modifications are easily conceivable within the category of the idea of the present invention by a person of ordinary skill in the art, and these modifications are also considered to belong to the scope of the present invention. For example, additions, deletions or changes in design of the constituent elements or additions, omissions or changes in condition of the processes may be arbitrarily made to the above embodiments by a person of ordinary skill in the art, and these modifications also fall within the scope of the present invention as long as they encompass the spirit of the present invention.

In addition, the other advantages of the aspects described in the above embodiments which are obvious from the descriptions of the specification or which are arbitrarily conceivable by a person of ordinary skill in the art are considered to be achievable by the present invention as a matter of course.

What is claimed is:

1. A display device comprising:
a substrate;
a first base electrode disposed above the substrate;
a rib formed of an inorganic insulating material and comprising an aperture overlapping the first base electrode;
a first lower electrode disposed at the aperture and electrically connected to the first base electrode;
a partition including a conductive lower part disposed on the rib and an upper part projecting from a side surface of the lower part;
a first organic layer configured to emit light of a first color and covering the first lower electrode; and
a first upper electrode disposed on the first organic layer and contacting the lower part, wherein
a periphery of the first base electrode is covered by the rib,
the first base electrode is formed of a first metal material,
a periphery of the first lower electrode is located on the rib,
the first lower electrode is formed of a second metal material different from the first metal material.

2. The display device of claim 1, further comprising:
a second base electrode disposed above the substrate, separated from the first base electrode, and formed of the first metal material;
a second lower electrode electrically connected to the second base electrode and formed of the second metal material;
a second organic layer configured to emit light of a second color different from the first color and covering the second lower electrode; and
a second upper electrode disposed on the second organic layer and contacting the lower part, wherein
a periphery of the second base electrode is covered by the rib,
a periphery of the second lower electrode is located on the rib, and
a thickness of the first lower electrode is different from a thickness of the second lower electrode.

3. The display device of claim 2, wherein
the second color is a color of a wavelength longer than a wavelength of the first color, and
the thickness of the second lower electrode is greater than the thickness of the first lower electrode.

4. The display device of claim 1, wherein
the first metal material is aluminum or an aluminum alloy, and
the second metal material is silver.

5. The display device of claim 1, wherein
a thickness of the first base electrode is greater than or equal to 50 nm.

6. The display device of claim 1, wherein
a thickness of the first lower electrode is greater than or equal to 10 nm.

7. The display device of claim 1, wherein
a thickness of the first lower electrode is smaller than a thickness of the first base electrode.

8. The display device of claim 2, wherein
the thickness of the second lower electrode is equal to a thickness of the second base electrode or smaller than the thickness of the second base electrode.

9. The display device of claim 2, wherein
the first lower electrode is in contact with the first base electrode, and
the second lower electrode is in contact with the second base electrode.

10. The display device of claim 2, further comprising:
a first middle electrode interposed between the first base electrode and the first lower electrode; and
a second middle electrode interposed between the second base electrode and the second lower electrode, wherein
respective peripheries of the first middle electrode and the second middle electrode are located on the rib, and
the first middle electrode and the second middle electrode are formed of a third metal material different from the second metal material.

11. The display device of claim 10, wherein
the third metal material is aluminum or an aluminum alloy.

12. The display device of claim 1, wherein
part of the first lower electrode is located on the upper part and is separated from a portion disposed at the aperture.

13. The display device of claim 1, further comprising:
a first transparent layer disposed on the first upper electrode; and
a second transparent layer disposed on the first transparent layer, wherein
a refractive index of the second transparent layer is smaller than a refractive index of the first transparent layer.

14. The display device of claim 13, further comprising
a sealing layer formed of an inorganic insulating material, disposed on the second transparent layer, and contacting the lower part, wherein
a refractive index of the sealing layer is greater than the refractive index of the second transparent layer.

15. A manufacturing method of a display device, comprising:
forming a metal layer of a first metal material above a substrate;
patterning the metal layer and forming a first base electrode;
forming a rib comprising an aperture overlapping the first base electrode and a partition including a conductive lower part located on the rib and an upper part projecting from a side surface of the lower part;
depositing a second metal material different from the first metal material and forming a first lower electrode electrically connected to the first base electrode;
forming a first organic layer on the first lower electrode; and
forming a first upper electrode which located on the first organic layer and is in contact with the lower part.

16. The manufacturing method of the display device of claim 15, wherein
the first metal material is aluminum or an aluminum alloy, and
the second metal material is silver.

17. The manufacturing method of the display device of claim 15, further comprising,
before forming the first lower electrode, depositing a third metal material different from the second metal material and forming a first middle electrode on the first base electrode.

18. The manufacturing method of the display device of claim 17, wherein
the third metal material is aluminum or an aluminum alloy.

19. The manufacturing method of the display device of claim 15, further comprising:
forming a first transparent layer on the first upper electrode;
forming a second transparent layer on the first transparent layer; and
forming a sealing layer which is located on the second transparent layer and which is in contact with the lower part.

20. The manufacturing method of the display device of claim 15, wherein
the first lower electrode and the first organic layer are continuously formed in a vacuum environment.
